(19) United States
(12) Patent Application Publication
(10) Pub. No.: US 2019/0346495 A1
(43) Pub. Date: Nov. 14, 2019

(54) DATA CONCENTRATION UNIT, POWER METER, AND METHOD FOR OPERATING SAME

(71) Applicant: KOREA ELECTRIC POWER CORPORATION, Naju-si (KR)

(72) Inventors: Tae-Gyeong KIM, Seoul (KR); Young-Hyun KIM, Daejeon (KR); Jong-Mock BAEK, Naju-si (KR); Byung-Kab JO, Gwangju (KR)

(21) Appl. No.: 16/335,192

(22) PCT Filed: Nov. 14, 2016
(86) PCT No.: PCT/KR2016/013072

§ 371 Date: Mar. 20, 2019

(30) Foreign Application Priority Data
Oct. 11, 2016 (KR) 10-2016-0131373

(51) Int. Cl. G01R 22/06; H04B 3/54; H04W 80/04; H04L 29/06

(52) U.S. Cl. CPC G01R 22/06; H04L 69/08; H04W 80/045; H04B 3/54

(57) ABSTRACT

The present invention relates to a data concentration unit, a power meter, and a method of operating the same. To this end, according to the present invention, there is a provided a data concentration unit that collects power metering data from power meters including a High-level Data Link Control (HDLC)-based power meter and an Internet Protocol-based power meter, and transmits the collected power metering data to an AMI server, wherein the power metering data is collected according to a communication model pre-configured for high-speed power line communication, and the communication model includes a high-speed power line communication MAC layer, an Internet Protocol layer, and an adaptation layer configured between the high-speed power line communication MAC layer and the Internet Protocol layer, the adaptation layer supporting communication with the HDLC-based power meter and with the Internet Protocol-based power meter.

### CROSS-REFERENCE TO RELATED APPLICATIONS

This application claims the benefit under 35 U.S.C. Section 371, of PCT International Application No. PCT/KR2016/013072, filed on Nov. 14, 2016, which claimed priority to Korean Patent Application No. KR 10-2016-0131373, filed on Oct. 11, 2016, the disclosures of which are hereby incorporated by the references.

### TECHNICAL FIELD

The present invention relates to a data concentration unit, a power meter, and a method of operating the same. More particularly, the present invention relates to a data concentration unit, a power meter, and a method of operating the same, wherein power metering data of an Internet Protocol communication type is transmitted and received in an AMI network based on a high-speed power line communication technology which conforms to ISO and IEC international standards.

### BACKGROUND ART

The existing Advanced Metering Infrastructure (AMI) network based on high-speed PLC is a method of building Neighborhood Networks by connecting a High-level Data Link Control (HDLC) serial communication type power meter to a high-speed power line communication modem (referring to FIG. 1). That is, this is a method of transmitting metering data subjected to encapsulation by HDLC method over the physical (PHY) layer and the medium access control (MAC) layer for high-speed power line communication.

A high-Speed power line communication is power line communication technology of 24 Mbps standardized by ISO/IEC 12139-1(2009) and is used to build the PHY layer and the MAC layer of Neighborhood networks for domestic low-voltage remote metering.

International standards related to electronic power meters and power metering is IEC 62056 Device Language Message Specification (DLMS) and applies to all domestic low-voltage electronic power meters.

In the power metering field in advanced counties, such as North America, Europe, and the like, in order to apply Internet technology to a future AMI network, the development of Internet Protocol (IP) type AMI communication devices and electronic power meters is in progress. When the IP type is applied to a power metering infrastructure, it is possible to intactly apply the existing device and the existing technology that have been used in the Internet. Therefore, it is possible to enhance the economic efficiency of development and production of devices, and it is easy to implement a very high-speed AMI communication, so that it is possible to construct a smart metering system such as real-time metering, and the like.

In the existing AMI network based on high-speed power line communication, only High-level Data Link Control (HDLC) communication scheme is used to load the upper layer protocol of the high-speed power line communication medium access control (MAC) layer, so that it is impossible to apply an IP-type electronic power meter and an Internet Protocol technology. This technical constraint is a main factor that makes it difficult to implement the very high-speed AMI network, to ensure compatibility with the Internet technologies, and to produce economical power meter devices.

Further, in the future, when IP-type electronic power meters come into wide use and are also used in the high-speed power line network, a means for operating HDLC-type and IP-type power metering devices that coexist has not been developed yet.

Regarding this, there is Korean Patent No. 1338003 (title: power line communication modem and power line communication system for electric vehicle charging).

### DISCLOSURE

### Technical Problem

The present invention is intended to propose a data concentration unit, a power meter, and a method of operating the same, wherein power metering data of an Internet Protocol communication type is transmitted and received in an AMI network based on a high-speed power line communication technology which conforms to ISO and IEC international standards.

### Technical Solution

In order to solve the above problems, according to the present invention, there is a provided a data concentration unit that collects power metering data from power meters including a High-level Data Link Control (HDLC)-based power meter and an Internet Protocol-based power meter, and transmits the collected power metering data to an AMI server, wherein the power metering data is collected according to a communication model pre-configured for high-speed power line communication, and the communication model includes a high-speed power line communication MAC layer, an Internet Protocol layer, and an adaptation layer configured between the high-speed power line communication MAC layer and the Internet Protocol layer, the adaptation layer supporting communication with the HDLC-based power meter and with the Internet Protocol-based power meter.

Further, the adaptation layer may include an IP service specific adaptation sublayer connecting the power metering data transmitted by protocol data of the Internet Protocol layer including IPv4 and IPv6, to the high-speed power line communication MAC layer.

Furthermore, the adaptation layer may further include an HDLC service specific adaptation sublayer connecting protocol data of a data link layer based on IEC 62056-46 HDLC to the high-speed power line communication MAC layer.

Furthermore, the adaptation layer may further include a common part adaptation sublayer having adaptation layer functions supported in common by the Internet Protocol layer and the data link layer based on IEC 62056-46 HDLC.

Further, the common part adaptation sublayer may be a lower layer than the IP service specific adaptation sublayer and the HDLC service specific adaptation sublayer.

Further, a CPAS frame used in the common part adaptation sublayer may be made up of a header part and an SSAS message, and the header part of the CPAS frame may be configured to include a source address information field, a destination address information field, and an Ethernet type information field.

Further, the Ethernet type information field may contain information on at least one among an IPv4 protocol, an IPv6 protocol, and an HDLC data link protocol.

Further, the SSAS message may be divided into an SSAS control packet and an SSAS data packet, and the SSAS control packet may perform an address resolution function fulfilled by an Address Resolution Protocol (ARP).

Further, the SSAS control packet may include a control type field, a source IP address field, a source CPAS address field, a destination IP address field, and a destination CPAS address field.

Further, the SSAS data packet may include a packet type field, a compression type field, an octet length field of data, and a data field.

In order to solve the above problems, according to the present invention, there is a provided a method of operating a data concentration unit, the method including: collecting power metering data from power meters including an HDLC-based power meter and an Internet Protocol-based power meter; and transmitting the collected power metering data to an AMI server, wherein the collecting of the power metering data is performed according to a communication model pre-configured for high-speed power line communication, and the communication model includes a high-speed power line communication MAC layer, an Internet Protocol layer, and an adaptation layer configured between the high-speed power line communication MAC layer and the Internet Protocol layer, the adaption layer supporting communication with the HDLC-based power meter and with the Internet Protocol-based power meter.

Further, the adaptation layer may include an IP service specific adaptation sublayer connecting the power metering data transmitted by protocol data of the Internet Protocol layer including IPv4 and IPv6, to the high-speed power line communication MAC layer.

Furthermore, the adaptation layer may further include an HDLC service specific adaptation sublayer connecting protocol data of a data link layer based on IEC 62056-46 HDLC to the high-speed power line communication MAC layer.

Furthermore, the adaptation layer may further include a common part adaptation sublayer having adaptation layer functions supported in common by the Internet Protocol layer and the data link layer based on IEC 62056-46 HDLC.

Further, the common part adaptation sublayer may be a lower layer than the IP service specific adaptation sublayer and the HDLC service specific adaptation sublayer.

Further, a CPAS frame used in the common part adaptation sublayer may be made up of a header part and an SSAS message, and the header part of the CPAS frame may include source address information, destination address information, and Ethernet type information.

Further, the Ethernet type information field may contain information on at least one among an IPv4 protocol, an IPv6 protocol, and an HDLC data link protocol.

Further, the SSAS message may be divided into an SSAS control packet and an SSAS data packet, and the SSAS control packet may perform an address resolution function fulfilled by an Address Resolution Protocol (ARP).

Further, the SSAS control packet may include a control type field, a source IP address field, a source CPAS address field, a destination IP address field, and a destination CPAS address field.

Further, the SSAS data packet may include a packet type field, a compression type field, an octet length field of data, and a data field.

In order to solve the above problems, according to the present invention, there is a provided a power meter generating power metering data for a consumer and transmitting the power metering data to a data concentration unit via a communication unit that is built in the power meter or is connected to the power meter outside, wherein the power meter is one among an HDLC-based power meter and an Internet Protocol-based power meter; the power metering data is transmitted to the data concentration unit according to a communication model pre-configured for high-speed power line communication; and the communication model includes a high-speed power line communication MAC layer, an Internet Protocol layer, and an adaptation layer configured between the high-speed power line communication MAC layer and the Internet Protocol layer, the adaptation layer supporting communication with the data concentration unit.

### Advantageous Effects

First, the data concentration unit, the power meter, and the method of operating the same according to the embodiment of the present invention have an advantage in that the AMI communication speed is improved. That is, according to the data concentration unit, the power meter, and the method of operating the same according to the embodiment of the present invention, by applying the Internet Protocol (IP) technology to the high-speed power line network, it is possible to overcome data transmission rate limitation caused by the inherent attribute of the existing HDLC serial communication type. That is, the metering data transmission speed is dramatically improved and enhanced in the high-speed power line network, thereby facilitating real-time metering which is the ultimate purpose of the AMI system.

Further, according to the data concentration unit, the power meter, and the method of operating the same according to the embodiment of the present invention, it is possible to enhance the compatibility and the economic efficiency by applying the IP-type electronic power meter. That is, according to the data concentration unit, the power meter, and the method of operating the same according to the embodiment of the present invention, the IP-type electronic power meter is usable in the AMI network based on high-speed power line communication, and the Internet protocol is applied to transmission of metering data between the electronic power meter and the metering server (Head End System), thereby enhancing compatibility with the external Internet-based information communication system. Accordingly, adoption of the IP-type power meter and enhancement of linkage compatibility with external systems may be a technical basis for economical construction of the AMI infrastructure.

Further, the data concentration unit, the power meter, and the method of operating the same according to the embodiment of the present invention may provide a technique of coexistence with the existing HDLC communication type devices. That is, the present invention enables HDLC-type and IP-type metering data to coexist on one MAC layer of the Neighborhood network for high-speed power line communication without changing or improving the existing power metering devices.

### DESCRIPTION OF DRAWINGS

FIG. 1 is a schematic diagram illustrating an AMI network.

FIG. 2 is a block diagram illustrating an AMI system that includes a data concentration unit according to an embodiment of the present invention.

FIG. 3 is a schematic diagram illustrating a communication model pre-configured for high-speed power line communication according to an embodiment of the present invention.

FIG. 4 is a schematic diagram illustrating a structure of a CPAS frame according to an embodiment of the present invention.

FIG. 5 is a flowchart illustrating a method of operating a data concentration unit according to an embodiment of the present invention.

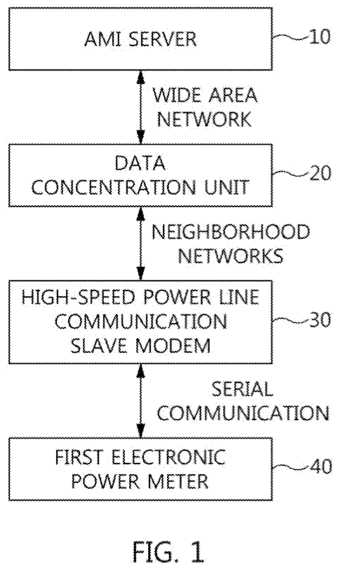

### MODE FOR INVENTION

The present invention will be described in detail with reference to the accompanying drawings. Here, a repeated description and a detailed description of known functions and configurations that make the subject matter of the present invention unclear will be omitted. The embodiments of the present invention are provided in order to fully explain the invention for those skilled in the art. Therefore, shapes and sizes of the elements in the drawings may be exaggerated for a more precise description.

Hereinafter, a data concentration unit, a power meter, and a method of operating the same according to an embodiment of the present invention will be described.

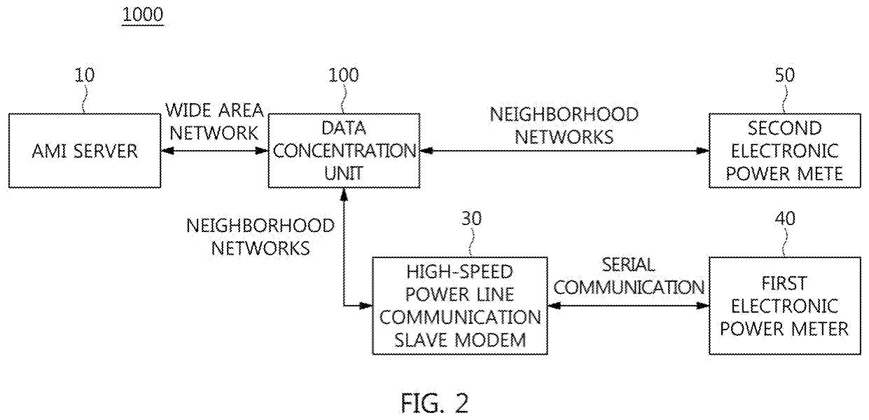

FIG. 2 is a block diagram illustrating an AMI system 1000 that includes a data concentration unit 100 according to an embodiment of the present invention. As described above, the data concentration unit 100 according to the embodiment of the present invention transmits and receives power metering data of an Internet Protocol communication type in the AMI network based high-speed power line communication technology which conforms to ISO and IEC international standards. In other words, the data concentration unit 100 according to the embodiment of the present invention collects power metering data from a first electronic power meter 40, which is an HDLC-based power meter, and a second electronic power meter 50, which is an Internet Protocol-based power meter, and transmits the result to an AMI server 10.

To this end, the data concentration unit 100 according to the embodiment of the present invention is configured such that the above object is achieved by designing the adaptation layer in such a manner as to load the Internet protocol on an upper layer of the high-speed power line communication medium access control (MAC) layer. The adaptation layer proposed in the present invention is made up of three adaptation sublayers and each of the sublayer protocols within the adaptation layer provides the following functions.

1) Linkage between the high-speed power line communication MAC and the Internet protocol

2) Coexistence of the HDLC-type upper layer and the IP-type upper layer in the same network

3) Acquisition of the high-speed power line communication station address (CPAS Address) through the IP address of a station

4) Designation of an IP header compression method and identification of the IP packet in which the header is compressed or not compressed.

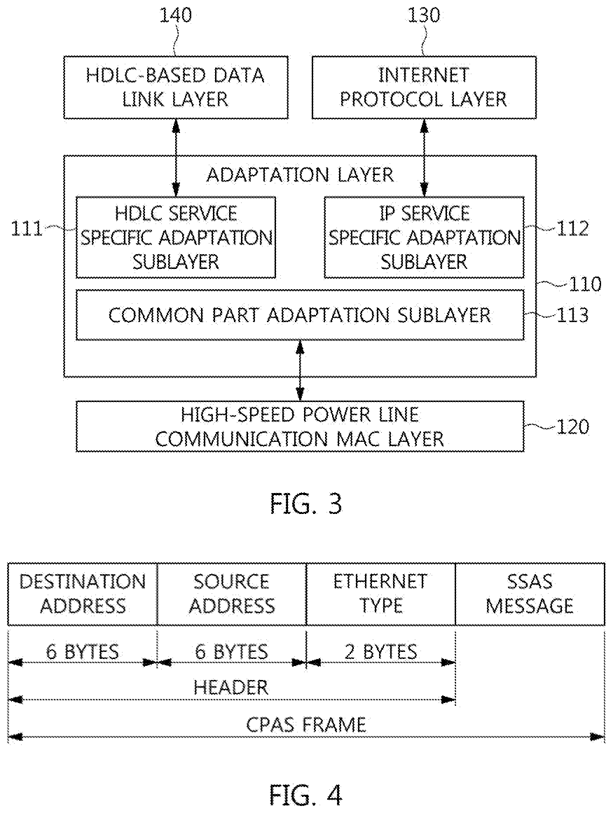

FIG. 3 is a schematic diagram illustrating a communication model pre-configured for high-speed power line communication according to an embodiment of the present invention. Hereinbelow, the communication model according to the embodiment of the present invention will be described with reference to FIG. 3.

As described above, the data concentration unit 100 according to the embodiment of the present invention collects power metering data obtained by an HDLC-type power meter as well as an IP-type power meter. To this end, the data concentration unit 100 according to the embodiment of the present invention performs communication using a communication model in a structure shown in FIG. 3. That is, regarding the communication model, in order to transmit the IP packet containing the power metering data via the high-speed power line network, an adaptation layer is added between an Internet Protocol layer 130 for the TCP/IP protocol and a high-speed power line communication medium access control (MAC) layer 120.

In other words, the communication model includes the high-speed power line communication MAC layer 120, the Internet Protocol layer 130, and the adaptation layer 110 configured between the high-speed power line communication MAC layer 120 and the Internet Protocol layer 130 to support communication between the HDLC-based power meter and the Internet Protocol-based power meter. In order to achieve the above-described object, the adaptation layer 110 may include an HDLC service specific adaptation sublayer 111, an IP service specific adaptation sublayer 112, and a common part adaptation sublayer 113.

The HDLC service specific adaptation sublayer (HDLC SSAS) 111 connects protocol data of the data link layer based on IEC 62056-46 HDLC to the high-speed power line communication MAC layer.

The IP service specific adaptation sublayer (IP SSAS) 112 connects the power metering data transmitted by the protocol data of the Internet Protocol layer including IPv4 and IPv6, to the high-speed power line communication MAC layer.

The common part adaptation sublayer 113 performs functions including adaptation layer functions supported in common by the Internet Protocol layer and the data link layer based on IEC 62056-46 HDLC. Further, in order to implement the above functions, the common part adaptation sublayer 113 may be positioned as a lower layer than the HDLC service specific adaptation sublayer 111 and the IP service specific adaptation sublayer 112, as shown in FIG. 3.

Further, the communication model according to the embodiment of the present invention may explicitly designate the upper protocol by setting the value of the Ethernet type information field in the CPAS frame supported by the common part adaptation sublayer 113. In general, the Ethernet type field is also present in the conventional Ethernet. However, in high-speed PLC technology, compatibility with the Ethernet has been considered from the beginning of the development, and it is designed to employ the inherent technical advantage of the Ethernet. Accordingly, the high-speed PLC technology is characterized in that the form of the payload on the PHY/MAC is similar to that of the Ethernet. However, since compatibility with the Ethernet is considered, the Ethernet type field actually determines the type of upper layer payload data transmitted by the Ethernet MAC. Accordingly, the present invention is characterized in that the type of SSAS message is identified by redefining the Ethernet type field.

Further, as shown in FIG. 4, the CPAS frame may be made up of a header part and an SSAS message. Further, the header part of the CPAS frame may be divided into three fields. The fields may include destination address information for specifying a high-speed power line communication destination address, source address information, and Ethernet type information, respectively. Further, the SSAS message is a protocol data unit for the HDLC service specific adaptation sublayer 111 or the IP service specific adaptation sublayer 112, and is made up of each SSAS layer header and payload data.

Further, the Ethernet type information field including the Ethernet type information, which is included in the header part of the CPAS frame, is as follows. The AMI network based on high-speed power line communication is implemented by loading the HDLC data link protocol or IP protocol containing the power metering data on the upper layer of the high-speed power line communication MAC layer 120. In the embodiment of the present invention, in order to use a power metering device using an HDLC communication scheme and a power metering device using an IP communication scheme together in one neighborhood network, a method of reading the value of the Ethernet type information field and explicitly distinguishing the protocol of the upper layer is proposed. Accordingly, the value of the Ethernet type information field included in the header part of the CPAS frame needs to be specified in advance by being explicitly distinguished with respect to the IPv4 protocol, the IPv6 protocol, the HDLC data link protocol, and the like.

Further, the SSAS message may be divided into an SSAS control packet and an SSAS data packet. Now, assuming that the power metering data is collected through the Internet Protocol layer 130, a description will be given. As described above, the SSAS message may be configured to include the SSAS control packet. The IP SSAS message may perform a CPAS address resolution function by using a control packet included in an IP SSAS message. That is, an IP SSAS data packet provides a function of transmitting IP data including the power metering data and an IP protocol header compression function. However, an IP SSAS control packet provides, in an AMI communication environment based on the high-speed power line communication medium access control (MAC), the same function as the address resolution performed by the Address Resolution Protocol (ARP) in the Internet Protocol stack.

Here, the control packet contained in the IP SSAS message may have a structure shown in Table 1 below, and the principle of CPAS address resolution is shown in Table 2 below.

TABLE 1

| Octets:1 | 1 | 4 or 16 | 16 | 4 or 16 | 16 |
|---|---|---|---|---|---|
| Packet_Type | CTL_Type | Sender_IP_ADDR | Sender_CPAS_ADDR | Target_IP_ADDR | Target_CPAS_ADDR |

TABLE 2

| | Length | Data | |
|---|---|---|---|
| Name | octets | Type | Description |
| Packet_Type | 1 | enum | [2] IPv4 Control packet of IP SSAS |
| | | | [3] IPv6 Control packet of IP SSAS |
| CTL_Type | 1 | enum | [0] AR_Requst_CMD |
| | | | [1] AR_Response_CMD |
| Sender_IP_ADDR | 4 or 16 | long^{—}unsigned | Sender's IP address |
| Sender_CPAS_ADDR | 6 | long^{—}unsigned | Sender's CPAS address |
| Target_IP_ADDR | 4 or 16 | long^{—}unsigned | Targer's IP address |
| Target_CPAS_ADDR | 6 | long^{—}unsigned | Target's CPAS address |

For example, when requesting address resolution, the value of CTR_Type field is set to 0x00. On the other hand, in the case of the response to the request, the value of the CTR_Type field is set to 0x01. When a sender node knows the IP address of the destination but does not know the CPAS address, an AR_Request_CMD request packet containing the IP address and the IP address length information of the sender and of the destination is generated and an AR Request CMD packet is transmitted. Here, a Target_CPAS_ADDR field of the request packet is filled with a series of OxFF (All bit-1s).

The destination node that has received the AR_Request_CMD packet puts its CPAS address into the Target_CPAS_ADDR. The other fields are copied from the corresponding fields of the AR_Request_CMD packet to generate an AR_Response_CMD packet for transmission to the sender. Here, AR_Request_CMD packet needs to be transmitted in a broadcast mode, and AR_Response_CMD packet needs to be transmitted in a unicast mode.

Further, the communication model according to the embodiment of the present invention may apply various IP header compression schemes. As described above, an IP SSAS packet may be divided into an IP SSAS data packet and an IP SSAS control packet. The IP SSAS data packet may be defined in the format shown in Table 3 to transmit the IP data including the power metering data and to provide the IP protocol header compression function. A description of each format is shown in Table 4.

TABLE 3

| Octets:1 | 1 | 2 | N |
|---|---|---|---|
| Packet_Type | Comp_Type | IP_Data_Len | IP_Data |

TABLE 4

| | Length | Data | |
|---|---|---|---|
| Name | octets | Type | Description |
| Packet_Type | 1 | enum | (0) IPv4 data packet of IP SSAS |
| | | | (1) IPv6 data packet of IP SSAS |
| Comp_Type | 1 | enum | (0) General IPv4 packet (No compression) |
| | | | (1) General IPv6 packet (No compression) |
| | | | (2) Van Jacobson header compression |
| | | | (RFC 1144) |
| | | | (3) IP header compression (RFC 2508) |
| | | | (4) ROHC (RFC 3095) |
| IP_Data_Len | 2 | long^{—}unsigned | Length in octets of the field IP_Data |
| IP_Data | N | octet⁻string | The general IP packet or the |
| | | | compressed IP packet |

In Tables 3 and 4, Packet Type denotes a packet type field, Comp_Type denotes a compression type field, IP_Data_Len denotes the octet length of data, and IP_Data denotes a data field. Technical Committee 13, a technical committee on a power metering field of International Electrotechnical Commission (IEC) which is a standards-making body in the field of electrical and electronics technologies, recommends implementation of the IP header compression function to implement an efficient AMI network.

In the embodiment of the present invention, three IP header compression functions are applied by setting the value of the Comp_Type field of the IP SSAS data packet header part, and compressed and non-compressed IP protocol packet data coexist in the same AMI network. That is, by reading the Comp_Type field of the received IP SSAS data packet, it is possible to identify five types of IP packet header formats, such as the IPv4 packet with the header not compressed, the IPv6 packet with the header not compressed, the IPv4 packet with the header compressed in IETF RFC 1144 scheme, the IP packet with the header compressed in RFC 2508 scheme, the IP packet with the header compressed in IETF RFC 3095 scheme, and the like. According to each identified compression scheme or standard, the received IP header may be decompressed into data before compression for reconstruction.

Further, by reading the Packet Type field of the received IP packet, version information of the IP packet is explicitly checked.

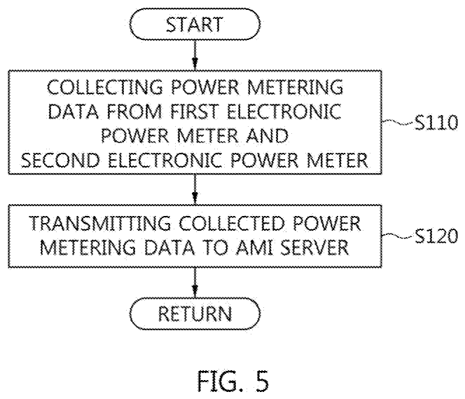

FIG. 5 is a flowchart illustrating a method of operating a data concentration unit according to an embodiment of the present invention. As described above, in the method of operating the data concentration unit according to the embodiment of the present invention, the power metering data of an Internet Protocol communication type may be transmitted and received in the AMI network based high-speed power line communication technology which conforms to ISO and IEC international standards.

At step S110, the power metering data is collected from the first electronic power meter, which is the HDLC-based power meter, and the second electronic power meter, which is the Internet Protocol-based power meter.

At step S120, the power metering data collected at step S110 is transmitted to the AMI server.

As described above, in the method of operating the data concentration unit according to the embodiment of the present invention, the adaptation layer is added between the high-speed power line communication MAC layer and the Internet Protocol layer to support communication with the HDLC and IP-based power meter, thereby collecting and transmitting data at steps S110 and S120. Here, the communication model including the adaptation layer, the sublayers included in the adaptation layer, the frame transmitted on the sublayer, the structure of the frame, and the like have been described in detail above, and the description thereof will be omitted.

Further, in the above description, the method of operating the data concentration unit according to the embodiment of the present invention is described as collecting data from the power meter and transmitting the data to the AMI server. However, this is only an example, and it is also possible to transmit the control signal generated from the AMI server to the power meter.

Also, in the above description, the communication model is described as being applied to the data concentration unit. However, this is only an example, and the above-described communication model is also applied to the power meter so as to be used in communication with the data concentration unit. That is, in the case of the power meter, the power metering data is transmitted to the data concentration unit via a communication unit (namely, a modem) built in the power meter or positioned outside thereof, and it is also possible to use the above-described communication model. Here, since the communication model applied to the power meter is the same as the communication model applied to the data concentration unit, a repeated description will be omitted.

The preferred embodiments of the present invention have been disclosed in the detailed description with reference to with the accompanying drawings. Although particular terms are used herein, they are merely intended to describe the present invention without limiting the meaning and the scope of the invention described in the claims. Therefore, it will be appreciated by those skilled in the art that various modifications and equivalent embodiments may be made in these embodiments. Accordingly, the scope of the invention will need to be defined in the accompanying claims.

1. A data concentration unit collecting power metering data from power meters and transmitting the collected power metering data to an AMI server,
wherein the power meters includes a High-level Data Link Control (HDLC)-based power meter and an Internet Protocol-based power meter; the data concentration unit collects the power metering data according to a communication model pre-configured for high-speed power line communication; and the communication model includes a high-speed power line communication MAC layer, an Internet Protocol layer, and an adaptation layer configured between the high-speed power line communication MAC layer and the Internet Protocol layer, the adaptation layer supporting communication with the HDLC-based power meter and with the Internet Protocol-based power meter.

2. The data concentration unit of claim 1, wherein the adaptation layer comprises an IP service specific adaptation sublayer connecting the power metering data transmitted by protocol data of the Internet Protocol layer including IPv4 and IPv6, to the high-speed power line communication MAC layer.

3. The data concentration unit of claim 2, wherein the adaptation layer further comprises an HDLC service specific adaptation sublayer connecting protocol data of a data link layer based on IEC 62056-46 HDLC to the high-speed power line communication MAC layer.

4. The data concentration unit of claim 3, wherein the adaptation layer further comprises a common part adaptation sublayer having adaptation layer functions supported in common by the Internet Protocol layer and the data link layer based on IEC 62056-46 HDLC.

5. The data concentration unit of claim 4, wherein the common part adaptation sublayer is a lower layer than the IP service specific adaptation sublayer and the HDLC service specific adaptation sublayer.

6. The data concentration unit of claim 4, wherein a CPAS frame used in the common part adaptation sublayer is made up of a header part and an SSAS message, and the header part of the CPAS frame is configured to include a source address information field, a destination address information field, and an Ethernet type information field.

7. The data concentration unit of claim 6, wherein the Ethernet type information field contains information on at least one among an IPv4 protocol, an IPv6 protocol, and an HDLC data link protocol.

8. The data concentration unit of claim 6, wherein the SSAS message is divided into an SSAS control packet and an SSAS data packet, and the SSAS control packet performs an address resolution function fulfilled by an Address Resolution Protocol (ARP).

9. The data concentration unit of claim 8, wherein the SSAS control packet includes a control type field, a source IP address field, a source CPAS address field, a destination IP address field, and a destination CPAS address field.

10. The data concentration unit of claim 8, wherein the SSAS data packet includes a packet type field, a compression type field, an octet length field of data, and a data field.

11. A method of operating a data concentration unit, the method comprising:
collecting power metering data from power meters including an HDLC-based power meter and an Internet Protocol-based power meter; and
transmitting the collected power metering data to an AMI server,
wherein the collecting of the power metering data is performed according to a communication model pre-configured for high-speed power line communication, and the communication model includes a high-speed power line communication MAC layer, an Internet Protocol layer, and an adaptation layer configured between the high-speed power line communication MAC layer and the Internet Protocol layer, the adaption layer supporting communication with the HDLC-based power meter and with the Internet Protocol-based power meter.

12. The method of claim 11, wherein the adaptation layer comprises an IP service specific adaptation sublayer connecting the power metering data transmitted by protocol data of the Internet Protocol layer including IPv4 and IPv6, to the high-speed power line communication MAC layer.

13. The method of claim 12, wherein the adaptation layer further comprises an HDLC service specific adaptation sublayer connecting protocol data of a data link layer based on IEC 62056-46 HDLC to the high-speed power line communication MAC layer.

14. The method of claim 13, wherein the adaptation layer further comprises a common part adaptation sublayer having adaptation layer functions supported in common by the Internet Protocol layer and the data link layer based on IEC 62056-46 HDLC.

15. The method of claim 14, wherein the common part adaptation sublayer is a lower layer than the IP service specific adaptation sublayer and the HDLC service specific adaptation sublayer.

16. The method of claim 14, wherein a CPAS frame used in the common part adaptation sublayer is made up of a header part and an SSAS message, and the header part of the CPAS frame includes source address information, destination address information, and Ethernet type information.

17. The method of claim 16, wherein the Ethernet type information field contains information on at least one among an IPv4 protocol, an IPv6 protocol, and an HDLC data link protocol.

18. The method of claim 17, wherein the SSAS message is divided into an SSAS control packet and an SSAS data packet, and the SSAS control packet performs an address resolution function fulfilled by an ARP.

19. The method of claim 18, wherein the SSAS control packet includes a control type field, a source IP address field, a source CPAS address field, a destination IP address field, and a destination CPAS address field,
wherein the SSAS data packet includes a packet type field, a compression type field, an octet length field of data, and a data field.

20. (canceled)

21. A power meter generating power metering data for a consumer and transmitting the power metering data to a data concentration unit via a communication unit that is built in the power meter or is connected to the power meter outside,
wherein the power meter is one among an HDLC-based power meter and an Internet Protocol-based power meter; the power metering data is transmitted to the data concentration unit according to a communication model pre-configured for high-speed power line communication; and the communication model includes a high-speed power line communication MAC layer, an Internet Protocol layer, and an adaptation layer configured between the high-speed power line communication MAC layer and the Internet Protocol layer, the adaptation layer supporting communication with the data concentration unit.
